(19) United States
(12) Patent Application Publication
(10) Pub. No.: US 2015/0228314 A1
(43) Pub. Date: Aug. 13, 2015

(54) LEVEL SHIFTERS FOR SYSTEMS WITH MULTIPLE VOLTAGE DOMAINS

(71) Applicant: QUALCOMM Incorporated, San Diego, CA (US)

(72) Inventors: Xiaoliang BAI, San Diego, CA (US); Arun Babu PALLERLA, San Diego, CA (US); Sei Seung YOON, San Diego, CA (US)

(73) Assignee: QUALCOMM Incorporated, San Diego, CA (US)

(21) Appl. No.: 14/176,705

(22) Filed: Feb. 10, 2014

(51) Int. Cl. G11C 7/10

(52) U.S. Cl. CPC G11C 7/1087

(57) ABSTRACT

A data latch includes a first stage configured to receive an input in a first voltage domain, and a second stage. The second stage includes a level shifter configured to shift the input from the first voltage domain to a second voltage domain, and an output circuit having a pull down circuit and pull up circuit arranged to generate an output in the second voltage domain, wherein the pull down circuit is responsive to the input in the first voltage domain and the pull up circuit is responsive to the input in the second voltage domain.

### BACKGROUND

1. Field

The present disclosure relates generally to electronic circuits, and more particularly, to level shifters for systems with multiple voltage domains.

2. Background

With the ever increasing demand for more processing capability in mobile devices, low power consumption has become a common design requirement. Various techniques are currently being employed to reduce power consumption in such devices. One such technique involves reducing the operating voltage of certain circuits in the device when certain operating conditions exist. As a result, different circuits may operate at different voltages. Level shifters may be used to interface these circuits by allowing a signal to pass from one voltage domain to another voltage domain.

### SUMMARY

Aspects of a data latch are disclosed. The data latch includes a first stage configured to receive an input in a first voltage domain, and a second stage having a level shifter configured to shift the input from the first voltage domain to a second voltage domain, and an output circuit having a pull down circuit and pull up circuit arranged to generate an output in the second voltage domain, wherein the pull down circuit is responsive to the input in the first voltage domain and the pull up circuit is responsive to the input in the second voltage domain.

Further aspects of a data latch are disclosed. The data latch includes receiving means for receiving an input in a first voltage domain, level shifting means for level shifting the input from the first voltage domain to a second voltage domain, and output generating means for generating an output in the second voltage domain, wherein the output generating means is configured to pull down the output in response to the input in the first voltage domain and the pull up the output in response to the input in the second voltage domain.

Aspects of a method for latching data are disclosed. The method includes receiving an input in a first voltage domain, level shifting the input from the first voltage domain to a second voltage domain, and generating an output in the second voltage domain using a pull down circuit responsive to the input in the first voltage domain to pull down the output, and using a pull up circuit responsive to the input in the second voltage domain to pull up the output.

It is understood that other aspects of apparatus and methods will become readily apparent to those skilled in the art from the following detailed description, wherein various aspects of apparatus and methods are shown and described by way of illustration. As will be realized, these aspects may be implemented in other and different forms and its several details are capable of modification in various other respects. Accordingly, the drawings and detailed description are to be regarded as illustrative in nature and not as restrictive.

### BRIEF DESCRIPTION OF THE DRAWINGS

Various aspects of apparatus and methods will now be presented in the detailed description by way of example, and not by way of limitation, with reference to the accompanying drawings, wherein:

FIG. 1 is a block diagram illustrating an exemplary embodiment of a memory.

FIG. 2 is a block diagram illustrating an exemplary embodiment of a peripheral circuit supported by memory.

FIG. 3 is a schematic representation of an exemplary embodiment of a bitcell for an SRAM.

FIG. 4 is a functional block diagram of an exemplary embodiment of an SRAM.

FIG. 5 is a functional block diagram of an exemplary embodiment of a data latch in an SRAM.

FIG. 6 is a flowchart illustrating a method of the operation for an exemplary embodiment of a data latch in an SRAM.

### DETAILED DESCRIPTION

The detailed description set forth below in connection with the appended drawings is intended as a description of various exemplary embodiments of the present invention and is not intended to represent the only embodiments in which the present invention may be practiced. The detailed description includes specific details for the purpose of providing a thorough understanding of the present invention. However, it will be apparent to those skilled in the art that the present invention may be practiced without these specific details. In some instances, well-known structures and components are shown in block diagram form in order to avoid obscuring the concepts of the present invention. Acronyms and other descriptive terminology may be used merely for convenience and clarity and are not intended to limit the scope of the invention.

Various apparatus and methods presented throughout this disclosure may be implemented in various forms of hardware. By way of example, any of these apparatus or methods, either alone or in combination, may be implemented as an integrated circuit, or as part of an integrated circuit. The integrated circuit may be an end product, such as a microprocessor, a digital signal processor (DSP), an application specific integrated circuit (ASIC), programmable logic, or any other suitable integrated circuit. Alternatively, the integrated circuit may be integrated with other chips, discrete circuit elements, and/or other components as part of either an intermediate product, such as a motherboard, or an end product. The end product can be any suitable product that includes integrated circuits, including by way of example, a cellular phone, personal digital assistant (PDA), laptop computer, a desktop computer (PC), a computer peripheral device, a multimedia device, a video device, an audio device, a global positioning system (GPS), a wireless sensor, or any other suitable device.

The word “exemplary” is used herein to mean serving as an example, instance, or illustration. Any embodiment described herein as “exemplary” is not necessarily to be construed as preferred or advantageous over other embodiments. Likewise, the term “embodiment” of an apparatus or method does not require that all embodiments of the invention include the described components, structure, features, functionality, processes, advantages, benefits, or modes of operation.

The terms “connected,” “coupled,” or any variant thereof, mean any connection or coupling, either direct or indirect, between two or more elements, and can encompass the presence of one or more intermediate elements between two elements that are “connected” or “coupled” together. The coupling or connection between the elements can be physical, logical, or a combination thereof. As used herein, two elements can be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

Any reference to an element herein using a designation such as “first,” “second,” and so forth does not generally limit the quantity or order of those elements. Rather, these designations are used herein as a convenient method of distinguishing between two or more elements or instances of an element. Thus, a reference to first and second elements does not mean that only two elements can be employed, or that the first element must precede the second element.

As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of the stated features, integers, steps, operations, elements, and/or components, but do not preclude the presence or addition of one or more other features, integers, steps, operations, elements, components, and/or groups thereof

Various aspects of level shifters for interfacing memory to peripheral circuits on an integrated circuit will now be presented. However, as those skilled in the art will readily appreciate, such aspects may be extended to other circuit configurations. According all references to a specific application for a level shifter is intended only to illustrate exemplary aspects of a level shifter with the understanding that such aspects may have a wide differential of applications.

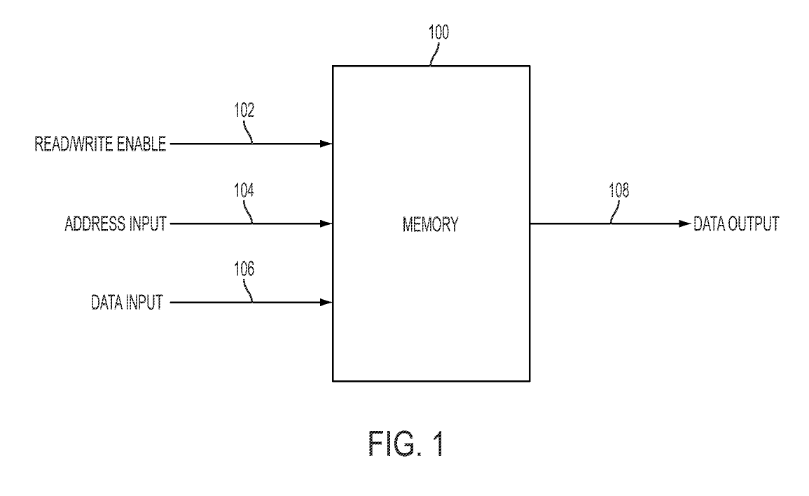

FIG. 1 is a block diagram illustrating an exemplary embodiment of a memory.

The memory 100 provides a medium for peripheral circuits to write and read program instructions and data. As used hereinafter, the term “data” will be understood to include program instructions, data, and any other information that may be stored in the memory 100. The memory 100 includes a read/write enable 102 for controlling the read/write operation of the memory 100. The memory 100 also includes an address input 104, a data input 106 for writing data to the memory 100 at the specified address, and a data output 108 for reading data from the memory 100 at the specified address. When writing data to the memory 100, a peripheral circuit sets the read/write enable to the write mode and sends to the memory 100 the address along with the data to be written to the memory 102 at that address. When reading data from the memory 100, the peripheral circuit 100 sets the read/write enable to the read mode and sends the address to the memory 100. In response, the memory 100 sends data at that address to the peripheral circuit.

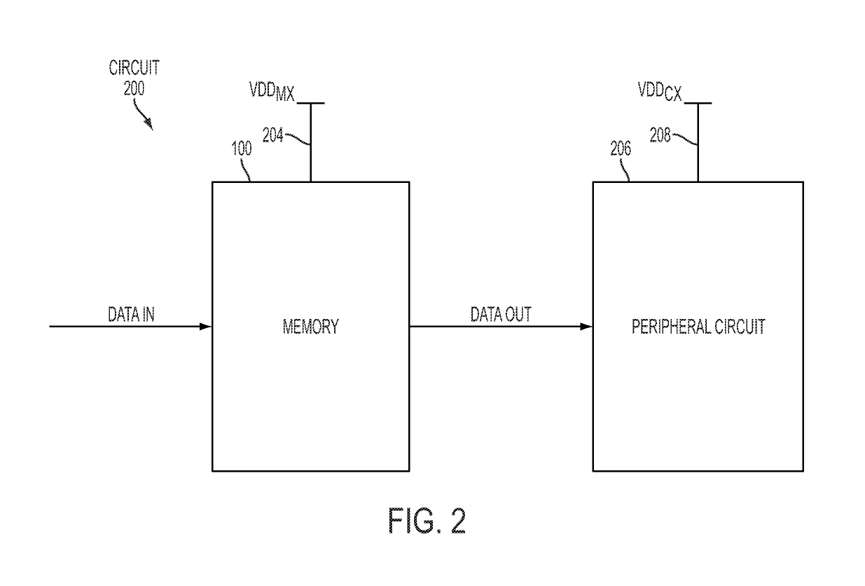

FIG. 2 is a block diagram illustrating an exemplary embodiment of a peripheral circuit supported by memory. The circuit 200 is shown with a memory 100 coupled to a first voltage rail VDD_{MX} 204 and a peripheral circuit 206 coupled to a second voltage rail VDD_{CX} 208. The peripheral circuit is to be construed broadly to include any suitable circuit that is peripheral to the memory 100 and capable of accessing the memory 100. In this example, the peripheral circuit 106 is shown reading data from the memory 100, however, as those skilled in the art will readily appreciate, the peripheral circuit 106 may also be capable of writing data to the memory 100.

The memory 100 may be any suitable storage medium, such as, by way of example, a static random access memory (SRAM). SRAM is volatile memory that requires power to retain data. However, as those skilled in the art will readily appreciate, the memory 102 is not necessarily limited to SRAM. Accordingly, any reference to SRAM is intended only to illustrate various concepts, with the understanding that such concepts may be extended to other memories.

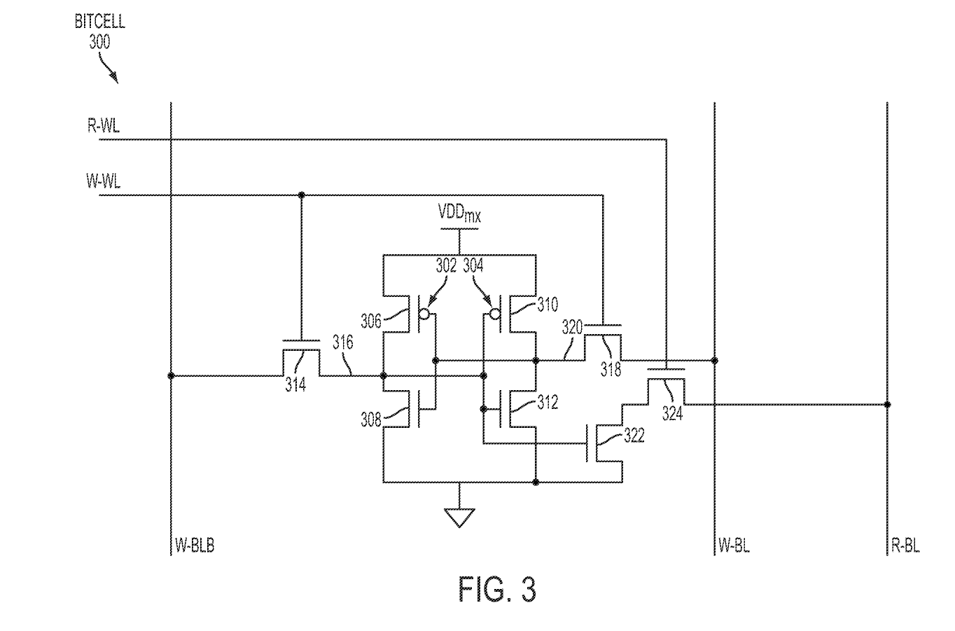

An SRAM includes an array of storage elements know as “bitcells.” Each bitcell is configured to store one bit of data. FIG. 3 is a schematic representation of an exemplary embodiment of a bitcell for an SRAM. The bitcell is implemented with an eight-transistor (8T) configuration. However, as those skilled in the art will readily appreciate, the bitcell may be implemented with a four-transistor (4T), six-transistor (6T), ten-transistor (10T) configuration, or any other suitable transistor configuration.

The bitcell 300 is shown with two inverters 302, 304. The first inverter 302 comprises a P-channel transistor 306 and an N-channel transistor 308. The second inverter 304 comprises a P-channel transistor 310 and an N-channel transistor 312. The first and second inverters 302, 304 are interconnected to form a cross-coupled latch. A first N-channel write access transistor 314 couples the output from the first inverter 302 to a first local write bitline W-BLB and a second N-channel write access transistor 318 couples the output from the second inverter 304 to a second local write bitline W-BL. The gates of the N-channel write access transistors 314, 318 are coupled to a write wordline W-WL. The output from the first inverter 302 is also coupled to the gate of an N-channel transistor 322. An N-channel read access transistor 324 couples the output from the N-channel transistor 322 to a local read bitline R-BL. The gate of the N-channel read access transistor 324 is coupled to a read wordline R-WL

The write operation is initiated by setting the local write bitlines W-BLB, W-BL to the value to be written to bitcell 300 and then asserting the write wordline W-WL. By way of example, a logic level 1 may be written to the bitcell 300 by setting the first local write bitline BLB to a logic level 0 and the second local write bitline BL to a logic level 1. The logic level 0 at the first local write bitline W-BLB is applied to the input of the second inverter 304 through the write access transistor 314, which in turn forces the output 320 of the second inverter 304 to a logic level 1. The output 320 of the second inverter 304 is applied to the input of the first inverter 302, which in turn forces the output 316 of the first inverter 302 to a logic level 0. A logic level 0 may be written to the bitcell 300 by inverting the values of the local write bitlines W-BLB, W-BL. The write local bitline drivers (not shown) are designed to be much stronger than the transistors in the bitcell 300 so that they can override the previous state of the cross-coupled inverters 302, 304.

The read operation is initiated by precharging the local read bitline R-BL to a logic level 1 and then asserting the read wordline R-WL. With the read wordline asserted, the output from the N-channel transistor 322 is transferred to the local read bitline R-BL through the read access transistor 324. By way of example, if the value stored at the output 320 of the second inverter 304 is a logic level 0, the output 316 from the first inverter 302 forces the N-channel transistor 322 on, which in turn causes the local read bitline R-BL to discharge to a logic level 0 through the read access transistor 324 and the N-channel transistor 322. If the value stored at the output 320 of the second inverter is a logic level 1, the output 316 from the first inverter 302 forces the N-channel transistor 322 off. As a result, the local read bitline R-BL remains charged to a logic level 1.

When the SRAM is in a standby mode, the write wordline W-WL and read wordline R-WL are set to a logic level 0. The logic level 0 causes the write access transistors 314, 316 and the read access transistor 324 to disconnect the write and read local bitlines W-BL, W-BLB, R-BL from the two inverters 302, 304. The cross-coupling between the two inverters 302, 304 maintains the state of the output as long as power is applied to the bitcell 300.

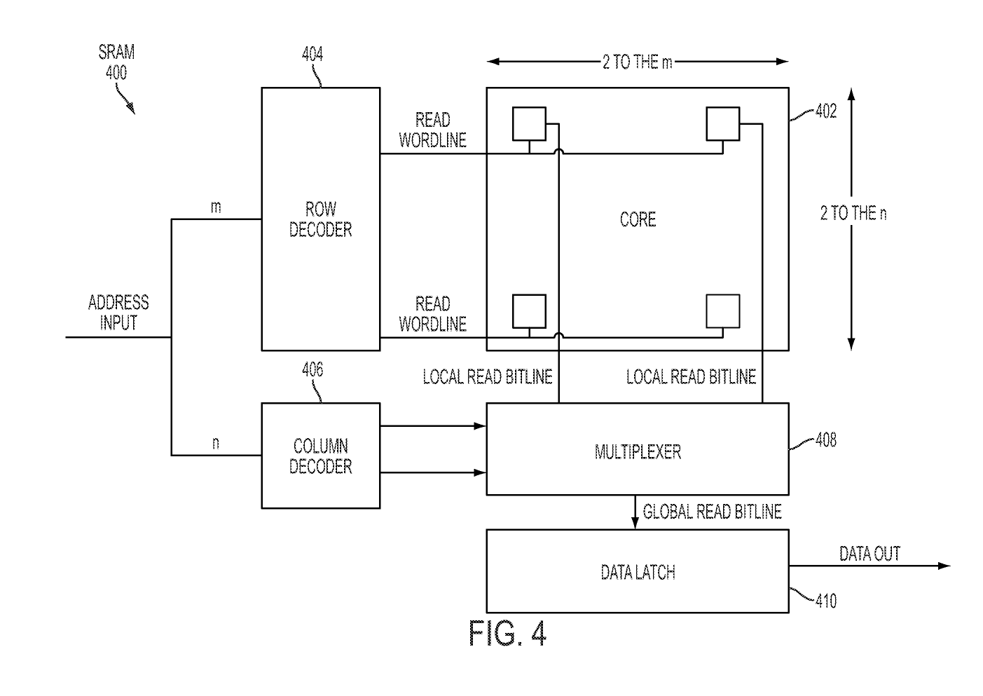

FIG. 4 is a functional block diagram of an exemplary embodiment of an SRAM. Various aspects of an SRAM will now be presented in the context of a read operation. Accordingly, for clarity of presentation, only the connections for the read operation are shown. Those skilled in the art will readily appreciate that additional connections are required to support the write operation.

The SRAM 400 includes a core 402 with supporting circuitry to decode addresses and perform read and write operations. The core 402 is comprised of bitcells arranged to share connections in horizontal rows and vertical columns. Specifically, each horizontal row of bitcells shares a read wordline and each vertical column of bitcells shares a local read bitline. The size of the core 402 (i.e., the number of bitcells) may vary depending on a variety of factors including the specific application, the speed requirements, the layout and testing requirements, and the overall design constraints imposed on the system. Typically, the core 402 will contain thousands of bitcells.

In the exemplary embodiment of the SRAM shown in FIG, 4, the core 402 is made up of (2ⁿ×2^{m}) bitcells arranged in 2ⁿ horizontal rows and 2^{m} vertical columns. A peripheral device (not shown) may randomly access any bitcell in the core 402 using an address that is (n+m) bits wide. In this example, n-bits of the address are provided to the input of a row decoder 404 and m-bits of the address are provided to the input of a column decoder 406. The SRAM 400 is placed into a read mode by the read/write enable signal (not shown). The read/write enable signal causes, among other things, the precharging of the local read bitlines.

The row decoder 404 converts the n-bit address into 2ⁿ read wordline outputs. A different read wordline is asserted by the row decoder 404 for each different n-bit row address. As a result, each of the 2^{m} bitcells in the horizontal row with the asserted read wordline is connected to one of the 2^{m} local read bitlines through its access transistor as described above in connection with FIG. 3. The 2^{m} local read bitlines are used to transmit the bits stored by the m bitcells to a multiplexer 408 that selects one or more bits from the 2^{m} bits transmitted on the local read bitlines. The number of bits that are selected by the multiplexer 408 is based on the width of the SRAM output. By way of example, the multiplexer 408 may select 64 of the 2^{m} bits to support an SRAM having a 64-bit output. In the described exemplary embodiment, the multiplexer 408 selects one of the 2^{m} bits. The selected bit may be referred to as a global read bitline. The global read bitline output from the multiplexer 408 is provided to a data latch 410 for further processing before being output to a peripheral circuit (not shown).

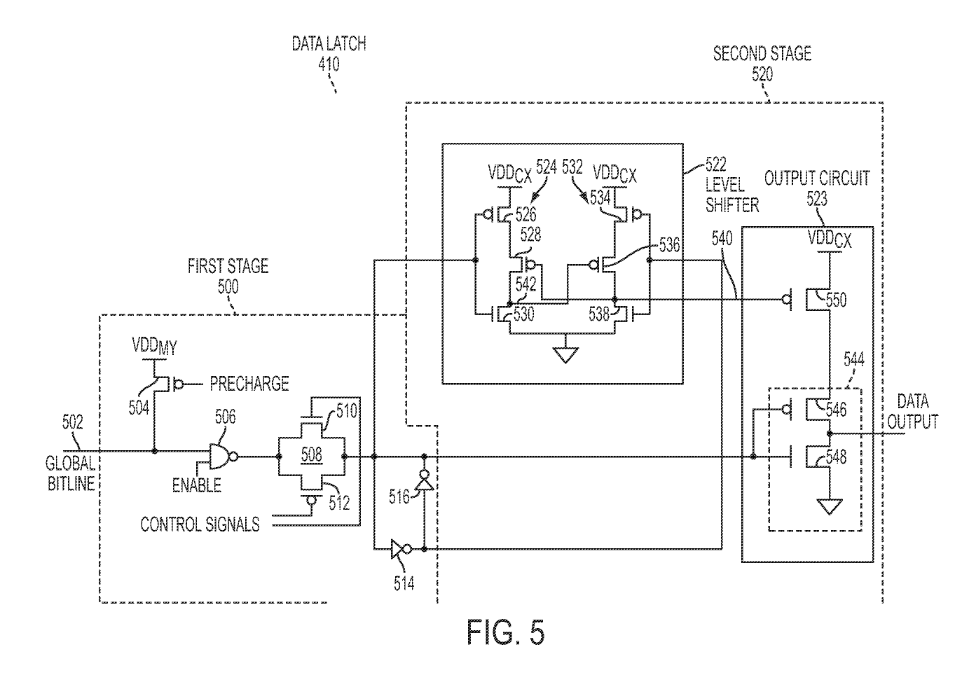

FIG. 5 is a functional block diagram of an exemplary embodiment of a data latch. The data latch 410 is shown with a first stage 500 that provides a means for receiving an input in a first voltage domain. In the exemplary embodiment described thus far, the first stage receives one of the global read bitlines 502 in the VDD_{MX} domain. The first stage 500 includes a P-channel transistor 504 to precharge the global bitline 502 to VDD_{MX} before the read operation. Once the global bitline 502 is precharged, the read operation may be performed. If the bit to be read out of the SRAM is a logic level 0, the global bitline 502 is discharged to ground through the output driver (not shown) of the multiplexer 408 (see FIG. 4). Conversely, if the bit to be read out of the SRAM is a logic level 1, the global bitline 502 remains charged to VDD_{MX}.

The global bitline 502 may be provided to a gate 506. In this example, the gate 506 is a NAND gate which provides a means for inverting the global bitline 502 when an enable signal is applied to one of the inputs. When the enable signal is not present, the data latch 410 is decoupled from the global bitline 502 which may provide additional functionality, such as, by way example, on-line testing of the data latch 410. In various embodiments of the data latch 410 that do not require this function, the NAND gate may be replaced with an inverter or bypassed completely with appropriate downstream circuitry to handle polarity.

The output from the gate 506 may be provided to a transmission gate 508, which in the described exemplary embodiment is implemented with two transistors 510, 512. Control circuitry (not shown) may be used to control the timing of the transmission gate 508 by providing control signals to the gates of the two transistors 510, 512. Two cross-coupled inverters 514, 516 operating in the VDD_{MX} domain provide a means for latching the bit on the read global bitline 502 at the output from the transmission gate 508.

The data latch 410 is also shown with a second stage 520 following the first stage 500. The second stage 520 includes a level shifter 522 and an output stage 523. In this embodiment, the level shifter 522 is used to shift the output from the first stage 500 from the VDD_{MX} domain to the VDD_{CX} domain, and the output circuit 523 is used to provide an output representative of the value stored in the selected bitcell in the VDDcx domain.

The level shifter provides a means for level shifting an input from the first voltage domain to a second voltage domain. The level shifter 522 includes two cross-coupled inverters. The first inverter 524 comprises a first P-channel transistor 526, a second P-channel transistor 528, and an N-channel transistor 530 connected in series between VDD_{CX} and ground. The second inverter 532 comprises a first P-channel transistor 534, a second P-channel transistor 536, and an N-channel transistor 538 connected in series between VDD_{CX} and ground. The output from the transmission gate 508 is connected to the gates of the first P-channel transistor 526 and the N-channel transistor 530 of the first inverter 524. The inverted latched output from the inverter 514 is connected to the gates of the first P-channel transistor 534 and the N-channel transistor 538 of the second inverter 532. The output from the first inverter 524 is connected to the gate of the second P-channel transistor 536 of the second inverter 532 and the output from the second inverter 532 is connected to the gate of P-channel transistor 528 of the first inverter 524.

When a logic level 0 from the transmission gate 508 is applied to the level shifter 522, the N-channel transistor 530 is turned off and the P-channel transistor 526 is turned on. At the same time, a logic level 1 is applied via the inverter 514 to the gate N-channel transistor 538, turning this transistor on, and to the gate of the P-channel transistor 534, turning this transistor partially off by reducing the gate-to-source voltage. As a result, the output 540 from the level shifter 522 is pulled down to ground. Due to the cross-coupling from the output 540 to the gate of the P-channel transistor 528, this transistor is on. Thus, both P-channel transistors 526, 528 are turned on, thereby pulling up node 542 to VDD_{CX}. Due to the cross-coupling from the node 542 to the gate of the P-channel transistor 536, this transistor is off

As the output from the transmission gate 508 transitions from a logic level 0 to a logic level 1, the N-channel transistor 530 turns on and begins to pull down the node 542 from VDD_{CX} to ground. This drop in voltage at the node 542 is opposed by the P-channel transistor 528, which is still on. However, the gate of the P-channel transistor 526 is pulled up to VDD_{MX}, which is closer to the transistor's source value of VDD_{CX}. Because the gate-to-source voltage of the P-channel transistor 526 is reduced, the transistor is partially turned off. In essence, applying VDD to the gate of the P-channel transistor 526 weakens the transistor and allows the N-channel transistor 530 to more easily pull down the node 542 to ground, which turns on the P-channel transistor 536. The logic level 0 from the inverter 514 turns off the N-channel transistor 538 and turns on the P-channel transistor 534. With both P-channel transistors 534, 536 turned on, the output 540 from the level shifter 522 is pulled up to VDD_{CX}.

Similarly, when the output from the transmission gate 508 transitions back to a logic level 0, the gate of the P-channel transistor 534 is pulled up to VDD_{MX}, turning this transistor partially off and making it easier for the N-channel transistor 538 to pull down the output 540 from the level shifter 522 to ground.

The output circuit 523 provides a means for generating an output in the second voltage domain. The output circuit 523 includes an inverter 544 and a pull up circuit 550. In this example, the inverter 544 is implemented with a P-channel transistor 546 and an N-channel transistor 548 and the pull up circuit 550 is implemented with a second P-channel transistor. The inverter 544 is configured to pull down the output from the data latch 410 to ground when the value stored in the selected bitcell is at a logic level 0. The pull up circuit 550 is configured to pull up the output from the data latch 410 to VDD_{CX} when the value stored in the selected bitcell is at a logic level 1.

When the value stored by the selected bitcell is at a logic level 0, the output from the transmission gate 508 is at a logic level 1. The output from the transmission gate 508 is shifted from the VDD_{MX} domain to the VDD_{CX} domain by the level shifter 522. The level shifted output is applied to the gate of the P-channel transistor 550 to turn off the transistor, thereby decoupling the VDD_{CX} from the inverter 544. At the same time, the logic level 1 output from the transmission gate 508 is applied directly to the input of the inverter 544, which turns off the P-channel transistor 546 and turns on the N-channel transistor 548, thereby pulling down the output of the data latch 410 to ground. The process does not need to wait until the p-channel transistor 550 turns off

When the value stored by the selected bitcell is at a logic level 1, the output from the transmission gate 508 is at a logic level 0, which is applied to the gate of the P-channel transistor 550 to turn on the transistor. At the same time, the logic level 0 output from the transmission gate 508 is applied directly to the input of the inverter 544, specifically, the gates of the P-channel transistor 546 and the N-channel transistor 548. As a result, the P-channel transistor 546 is turned on and the N-channel transistor 548 is turned off. With both P-channel transistors 546, 550 turned on, the output of the data latch 410 is pulled up to VDD_{CX}.

Thus, one can readily see that the output of the data latch 410 pulls down quicker than it pulls up. This is because the output is pulled down by the inverter 544 directly from the output from the transmission gate 508 when the value stored in the selected bitcell is a logic level 0. When the value stored by the selected bitcell is a logic level 1, the output of the data latch 410 is pulled up by pull up circuit 550 which is driven by the level shifter 522. The level shifter 522 results in additional propagation delay through the data latch 410. The quicker response time for pull down is desirable, however, because of the additional time required to discharge the global read bitline when the value stored by the selected bitcell is a logic level 0.

In this exemplary embodiment, the pull down circuit 544 is responsive to the output of the data transmission gate 508 in the VDD_{MX} domain. The level shifter 522 is placed in the path between the data transmission gate 508 and the pull up circuit 550. As a result, the pull up circuit 550 is responsive to the output of the level shifter 522 in the VDD_{CX} domain. The exemplary embodiment has been described for a case that VDDcx is higher than VDD_{MX}. However, one of ordinary skill in the art would readily recognize that the exemplary embodiment would operate for the case that VDD is higher than VDD_{CX}, without modification.

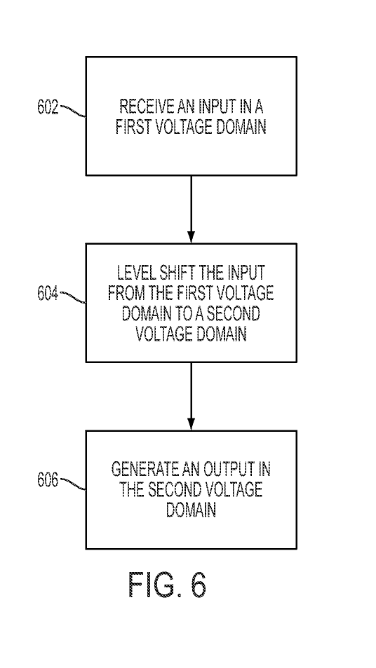

FIG. 6 is a flowchart illustrating a method of the operation for an exemplary embodiment of a data latch. The method begins with block 602 where an input in a first voltage domain is received by the data latch. The received input may be a global bitline. Once received, the input is level shifted from the first voltage domain to a second voltage domain in block 604. The level shifting may be performed using first and second cross-coupled inverters configured to be powered by a voltage source in the second voltage domain, or by some other suitable means. In block 606, an output in a second voltage domain is generated by the data latch. The output may be generated using a pull down circuit responsive to the input in the first voltage domain to pull down the output, and using a pull up circuit responsive to the input in the second voltage domain to pull up the output.

The specific order or hierarchy of blocks in the method of operation described above is provided merely as an example. Based upon design preferences, the specific order or hierarchy of blocks in the method of operation may be re-arranged, amended, and/or modified. The accompanying method claims include various limitations related to a method of operation, but the recited limitations are not meant to be limited in any way by the specific order or hierarchy unless expressly stated in the claims.

The various aspects of this disclosure are provided to enable one of ordinary skill in the art to practice the present invention. Various modifications to exemplary embodiments presented throughout this disclosure will be readily apparent to those skilled in the art, and the concepts disclosed herein may be extended to other magnetic storage devices. Thus, the claims are not intended to be limited to the various aspects of this disclosure, but are to be accorded the full scope consistent with the language of the claims. All structural and functional equivalents to the various components of the exemplary embodiments described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112(f) unless the element is expressly recited using the phrase “means for” or, in the case of a method claim, the element is recited using the phrase “step for.”

What is claimed is:

1. A data latch, comprising:
a first stage configured to receive an input in a first voltage domain; and
a second stage comprising a level shifter configured to shift the input from the first voltage domain to a second voltage domain, and an output circuit having a pull down circuit and pull up circuit arranged to generate an output in the second voltage domain, wherein the pull down circuit is responsive to the input in the first voltage domain and the pull up circuit is responsive to the input in the second voltage domain.

2. The data latch of claim 1 wherein the input to the first stage comprises a global bitline output from memory during a read operation.

3. The data latch of claim 1 wherein the output circuit is configured to pull up the output through the pull up circuit when the input to the first stage is in a charged state and to pull down the output through the pull down circuit when the input to the first stage is in a discharged state.

4. The data latch of claim 1 wherein the first stage comprises a latch configured to latch the input.

5. The data latch of claim 1 wherein the first stage comprises a gate configured to invert the input, and wherein the output circuit is configured as an inverter.

6. The data latch of claim 1 wherein the pull down circuit comprises an inverter having a P-channel transistor and an N-channel transistor, and the pull up circuit comprises a P-channel transistor configured to be connected between the inverter and a voltage source in the second voltage domain.

7. The data latch of claim 1 wherein the level shifter comprises first and second cross-coupled inverters configured to be powered by a voltage source in the second voltage domain.

8. A data latch, comprising:
receiving means for receiving an input in a first voltage domain;
level shifting means for level shifting the input from the first voltage domain to a second voltage domain; and
output generating means for generating an output in the second voltage domain, wherein the output generating means is configured to pull down the output in response to the input in the first voltage domain and the pull up the output in response to the input in the second voltage domain.

9. The data latch of claim 8 wherein the input to the receiving means comprises a global bitline output from memory during a read operation.

10. The data latch of claim 8 wherein the receiving means comprises means for latching the input.

11. The data latch of claim 8 wherein the receiving means comprises means for inverting the input, and wherein the output generating means is configured as an inverter.

12. The data latch of claim 8 wherein the level shifting means comprises first and second cross-coupled inverters configured to be powered by a voltage source in the second voltage domain.

13. A method of latching data, comprising:
receiving an input in a first voltage domain;
level shifting the input from the first voltage domain to a second voltage domain; and
generating an output in the second voltage domain using a pull down circuit responsive to the input in the first voltage domain to pull down the output, and using a pull up circuit responsive to the input in the second voltage domain to pull up the output.

14. The method of claim 13 wherein the received input comprises a global bitline output from memory during a read operation.

15. The method of claim 13 wherein the receiving an input comprises latching the input.

16. The method of claim 13 wherein the receiving an input comprises inverting the input, and wherein the generating an output comprising generating the output using an output circuit configured as an inverter.

17. The method of claim 13 wherein the level shifting the input comprises level shifting the input using first and second cross-coupled inverters configured to be powered by a voltage source in the second voltage domain.
